(19) United States
(12) Patent Application Publication
(10) Pub. No.: US 2012/0090663 A1
(43) Pub. Date: Apr. 19, 2012

(54) DERIVING ECONOMIC VALUE FROM WASTE HEAT FROM CONCENTRATED PHOTOVOLTAIC SYSTEMS

(75) Inventor: Douglas Kiesewetter, Montrose, CO (US)

(73) Assignee: BRIGHTLEAF TECHNOLOGIES INCORPORATED, Montrose, CO (US)

(21) Appl. No.: 13/271,404

(22) Filed: Oct. 12, 2011

Related U.S. Application Data
(60) Provisional application No. 61/393,736, filed on Oct. 15, 2010.

(51) Int. Cl. H01L 31/058

(52) U.S. Cl. 136/248

(57) ABSTRACT

A method and apparatus for capturing solar energy for use with a structure. A solar energy system collects solar energy, some of which is converted into electricity and some of which is stored in subterranean thermal banks. Waste heat is formed in solar cells during the conversion of solar energy into electricity. A fluid flow system is provided that transfers heat from the solar cells into a subterranean formation via wellbores that penetrate the subterranean formation. The heat remains in the formation and is selectively transferred to the structure through the fluid flow system.

### RELATED APPLICATION

This application is a non-provisional of and claims priority to and the benefit of U.S. Provisional Patent Application No. 61/393,736, filed on Oct. 15, 2010, incorporated herein by reference in it's entirety.

### BACKGROUND

1. Field of Invention

The invention relates generally to an improved efficiency concentrated photovoltaic (CPV) system. More specifically, the invention relates generally to a method and system for geothermally storing waste heat from a CPV system.

2. Description of Prior Art

Converting solar energy into electricity is often accomplished by directing the solar energy onto one or more photovoltaic cells. The photovoltaic cells are typically made from semiconductors, that can absorb energy from photons from the solar energy, and in turn generate electron flow within the cell. A solar panel is a group of these cells that are electrically connected and packaged so an array of panels can be produced; which is typically referred to as a flat panel system. Solar arrays are typically disposed so they receive rays of light directly from the source.

Some solar collection systems concentrate solar energy by employing curved solar collectors that concentrate light onto a solar cell. The collectors are often parabolic having a concave side and a convex side, and usually with the concave side facing forward for directing reflecting light onto a receiver. Receivers typically include a photovoltaic cell that has a higher performance than cells used in flat panel systems. A reflective surface is typically on the concave side of each collectors for reflecting the solar energy towards the receiver. The concave configuration of the reflective surface converges reflected rays of solar energy to concentrate the rays when contacting the receiver. Concentrating the solar energy with the curved collectors can project up to about 1500 times the intensity of sunlight onto a receiver over that of a flat panel system. As the cells currently do not convert all the solar energy received into electricity, substantial heating occurs on the receiver that can damage the cells unless the thermal energy accumulated on the receiver can be transferred elsewhere.

Solar collection systems that concentrate solar energy generally employ a number of collectors; each having a reflective side configured to focus the reflected light onto a solar receiver. Because the solar energy is concentrated, the reflective surface area exceeds the conversion cell area by a significant amount. Solar collection and conversion systems often consolidate the collectors into a solar array, thereby boosting the electricity generating capacity of the conversion system. The collectors within an array are typically positioned within a localized area to minimize the total area of the array.

### SUMMARY OF THE INVENTION

Provided herein is a method of processing solar energy. In one example embodiment the method involves converting solar energy to electricity and heat with a solar cell that is in the path of solar rays. The example method further includes directing the electricity to a load and transferring the heat from the solar cell to a geothermal well. Optionally, the method further includes transferring the heat from the geothermal well to a structure for heating the structure. In one example, ambient temperature when the heat is transferred to the geothermal well exceeds ambient temperature when the heat is transferred from the geothermal well to the structure. In an example where the geothermal well is a heating geothermal well, the method may further include transferring heat from the structure to a cooling geothermal well to cool the structure. In an alternative, the electricity generated with the cell is used to power the structure. In examples when the heat from the geothermal well is transferred to the structure, the amount of energy within the solar rays transferred to the structure increases from about 30% to about 80%. In one example embodiment, a solar collector reflects and concentrates the solar rays onto the solar cell. Alternatively, a flow of fluid thermally communicates with the solar cell and flows into the geothermal well thereby transferring the heat from the solar cell to the geothermal well.

Also disclosed herein is a solar energy system, that in one example includes a solar receiver having a solar cell that is selectively disposed in a path of solar rays and that is in selective electrical communication with an electrical load. The embodiment of the solar energy system also includes a heat transfer circuit having a charging branch and a consuming branch. The charging branch of this embodiment has a portion in thermal communication with the solar cell and a portion in thermal communication with a geothermal well; a selective heat transfer path is defined between the solar cell and the geothermal well through the charging branch. The consuming branch of this embodiment has a portion in thermal communication with the geothermal well and a portion in thermal communication with a structure; a selective heat transfer path is defined between the geothermal well and the structure through the consuming branch. In an alternative, the solar cell includes a concentrated photovoltaic cell that receives concentrated solar rays. Optionally, the heat transfer circuit includes fluid flow lines that transport a heat transfer fluid and wherein valves in the heat transfer circuit selectively open and close to divert the heat transfer fluid along a designated heat transfer path. In an alternative, the electrical load is disposed in the structure. In an example embodiment, energy in the solar rays is converted to heat and electricity in the solar receiver is transferred to the structure at an efficiency of about 80%. The heat transfer circuit may include a heat transfer fluid that selectively flows through a conduit formed in the solar receiver.

Yet further disclosed herein is a solar energy system that is made up of a solar collector having a reflective convex surface shaped to reflect and concentrate solar rays into an image. This embodiment of the solar energy system also includes a solar receiver having a solar cell strategically disposed to receive the image thereon and electrically conducting leads that connect the solar cell to an electrical load disposed in a structure. A heat transfer circuit is included that includes an energizing branch in thermal communication with the solar cell and a geothermal well. The energizing branch and geothermal well define a heat transfer path between the solar cell and geothermal well. The heat transfer circuit of this embodiment also includes a dissipating branch that is in thermal communication with the geothermal well and the structure. Thermal communication between the geothermal well and structure define a heat transfer path between the geothermal well and the structure. In one optional embodiment, the energizing branch and dissipating branch each have conduit for transporting fluid having a heat capacity. Valves are optionally included in the heat transfer circuit that selectively open and close so that the fluid is flowing through the energizing branch or the dissipating branch. In an optional embodiment, the geothermal well is a substantially vertical borehole and a portion of the heat transfer circuit has conduit that is suspended in the borehole and a heat transfer medium is provided between the conduit and walls of the borehole.

### BRIEF DESCRIPTION OF THE DRAWINGS

Some of the features and benefits of the present invention having been stated, others will become apparent as the description proceeds when taken in conjunction with the accompanying drawings, in which:

FIG. 1 is a schematic view of an example embodiment of a solar energy system in accordance with the present invention.

FIG. 2 is a side perspective view of an example of an array for use with the solar energy system of FIG. 1.

FIG. 3 is a side sectional view of the array of FIG. 2.

FIG. 4 is a partial sectional and perspective view of an example solar energy system for use with a structure in accordance with the present invention.

FIG. 5 is an alternate embodiment of the solar energy system of FIG. 4.

FIG. 6 is a schematic view of a heater transfer circuit for use with the solar energy system of FIG. 1.

While the invention will be described in connection with the preferred embodiments, it will be understood that it is not intended to limit the invention to that embodiment. On the contrary, it is intended to cover all alternatives, modifications, and equivalents, as may be included within the spirit and scope of the invention as defined by the appended claims.

### DETAILED DESCRIPTION OF INVENTION

The method and system of the present disclosure will now be described more fully hereinafter with reference to the accompanying drawings in which embodiments are shown. The method and system of the present disclosure may be in many different forms and should not be construed as limited to the illustrated embodiments set forth herein; rather, these embodiments are provided so that this disclosure will be thorough and complete, and will fully convey its scope to those skilled in the art. Like numbers refer to like elements throughout.

It is to be further understood that the scope of the present disclosure is not limited to the exact details of construction, operation, exact materials, or embodiments shown and described, as modifications and equivalents will be apparent to one skilled in the art. In the drawings and specification, there have been disclosed illustrative embodiments and, although specific terms are employed, they are used in a generic and descriptive sense only and not for the purpose of limitation. Accordingly, the improvements herein described are therefore to be limited only by the scope of the appended claims.

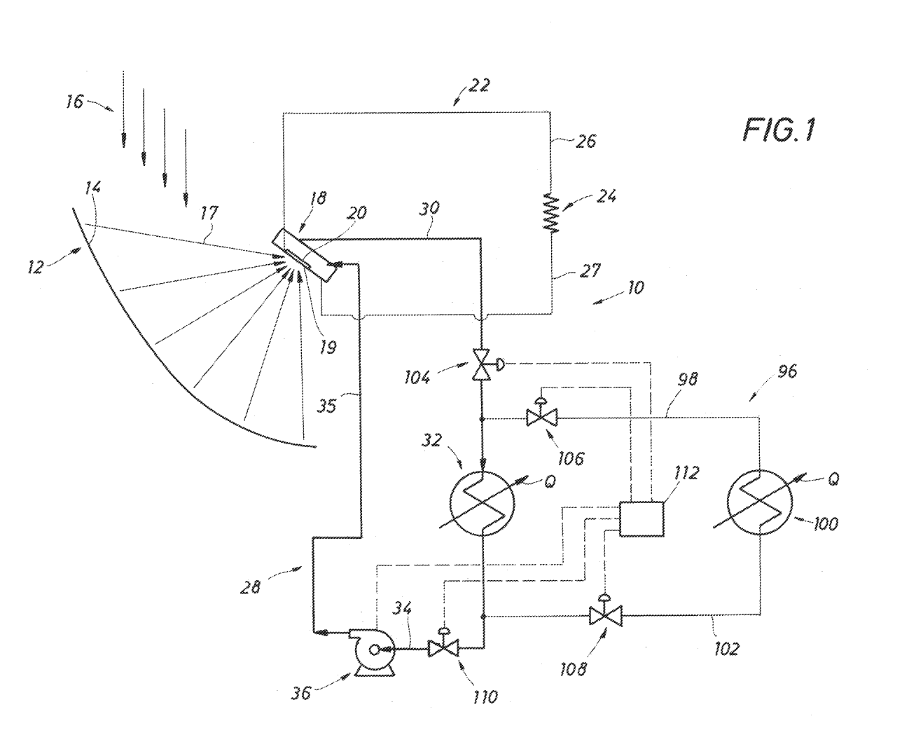

FIG. 1 provides in schematic view an example embodiment of a solar energy collection system 10 having a curved collector 12 and a reflective surface 14 on a concave side of the collector 12. In one example embodiment the collector 12 has a parabolic shape. In the example of FIG. 1, the collector 12 is disposed in the path of solar rays 16 that strike the reflective surface 14 and are redirected as reflected rays 17. The reflected rays 17 are shown traveling on a path towards a solar receiver 18 shown spaced back from the reflective surface 14. The collector 12 is shaped and contoured so that the reflective rays 17 form a defined image 19 with a flux density more concentrated than that of the solar rays 16. In the example of FIG. 1, a photovoltaic cell 20 is shown on the receiver 18 that coincides with formation of the image 19. The photovoltaic cell 20 converts the concentrated energy in the image 19 into electrical current that flows into a circuit 22 that the photovoltaic cell 20 is connected. Further illustrated in the example of FIG. 1, is an electrical load 24 schematically represented within the circuit 22. Electrical lines 26, 27 provide electrical communication between the photovoltaic cell 20 and load 24, thereby completing the circuit 22.

As is known, substantial heating may occur within the receiver 18 from the high flux density image 19 being cast on the photovoltaic cell 20. A heat transfer circuit 28 is illustrated for dissipating heat from the receiver 18, thereby protecting the photovoltaic cell 20 and other associated electronics (not shown) from overheating. Furthermore, controlling temperature within the photovoltaic cell 20 provides for an optimum efficiency within the photovoltaic cell 20 as efficiency of the photovoltaic cell 20 falls with increased temperatures. In the example of FIG. 1, the heat transfer circuit 28 includes a fluid flow line 30 that has an end connected to the receiver 18 and an opposing end attached to an inlet of a heat exchanger 32. In the example of FIG. 1, fluid flows through the fluid flow line 30 away from the receiver 18 into the heat exchanger 32; wherein heat represented by the notation Q is being removed from the fluid. After entering the heat exchanger 32 the fluid is directed through tubes within the heat exchanger 32 and to the exit of the heat exchanger 32. Fluid flow lines 34, 35 provide a path for the now cooled fluid to return to the receiver 18 so that additional heat may be removed from the receiver 18 and then dissipated within heat exchanger 32. A pump 36 is shown inserted between the lines 34, 35 for circulating the fluid through the heat transfer circuit 28.

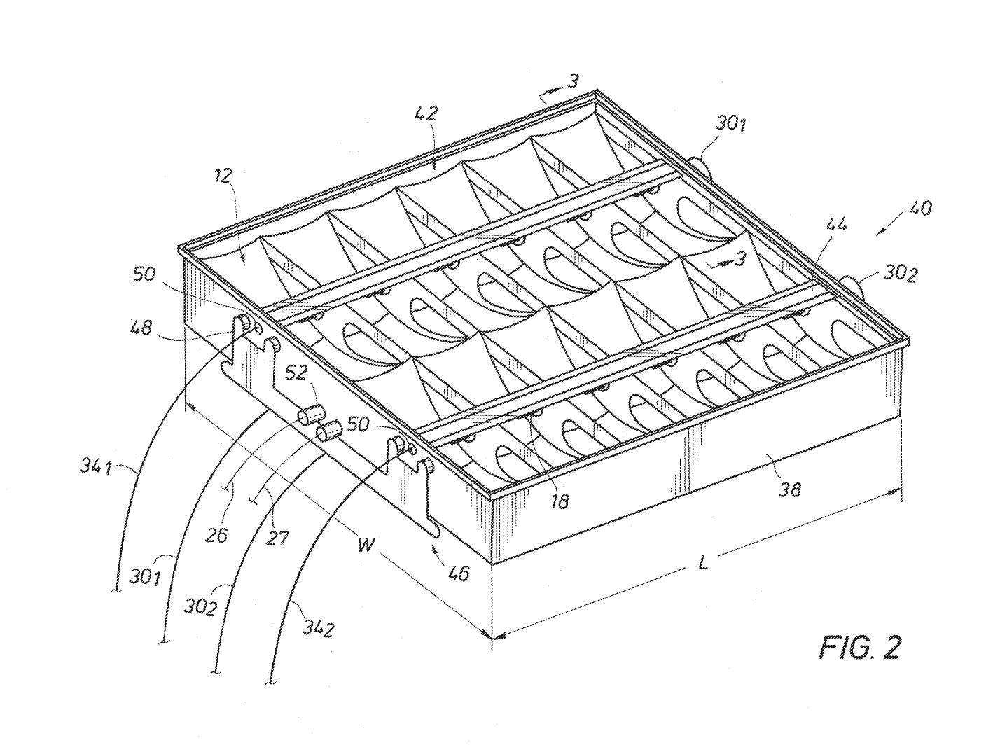

Referring now to FIG. 2, a number of collectors 12 are shown disposed within a rectangular shaped housing 38; the collectors 12 are arranged into an array 40 within the housing 38. The housing 38 has a lower bottom surface and a transparent cover 42 on its upper end placed over the array 40. The collectors 12 of FIG. 2 are oriented with their concave surfaces facing upwards and towards the cover 42 and are arranged in pairs of rows 43 that are aligned substantially parallel with a length L of the housing 38. Within each row the collectors 12 of FIG. 2 are arranged so that lines running parallel to the respective lengths of each collector 12 are substantially perpendicular to the length L of the housing 38. The length of the collectors 12 can exceed their widths, can be substantially the same as their widths, or be less than their widths. As shown in FIG. 2, the collectors 12 are tilted so that the middle section of the pairs of rows 43 are proximate the bottom of the housing 38, thus the outer lateral sides of the pairs of rows 43 are proximate the cover 42. Substantially longitudinal beams 44 are shown extending lengthwise within the housing 38 and disposed above the collectors 12. Beams 44 are substantially aligned with the middle portion of the pairs of rows 43. Receivers 18 are shown provided on an oblique edge of the beams 44. Strategically arranging the beams 43 with the middle portion of the pairs of rows 43 and the oblique positioning of the receivers 18 aligns the cell 20 with the image 19 (FIG. 1) for the generation of electricity.

A substantially planar bracket 46 is shown mounted on a lateral side of the housing 38 and on a side corresponding to a width W of the housing 38. The bracket 46 has planar end portions 48 projecting upward from a lower portion of the housing 38 and shown being fastened into the side of the housing 38. Positioned above the end pieces 48 are fittings 50 that provide connection between fluid flow lines 34₁, 34₂ in which cooling fluid is being carried back to the beam 44 for cooling the receivers 18. Flow lines 30₁, 30₂ are shown coupled to a side of the housing 38 distal from the connection of flow lines 34₁, 34₂. The upper portion of the midsection of the bracket 46 is cut away, in the cut away connectors 52 are shown mounted into the side wall of the housing 34 for connection of lines 26, 27.

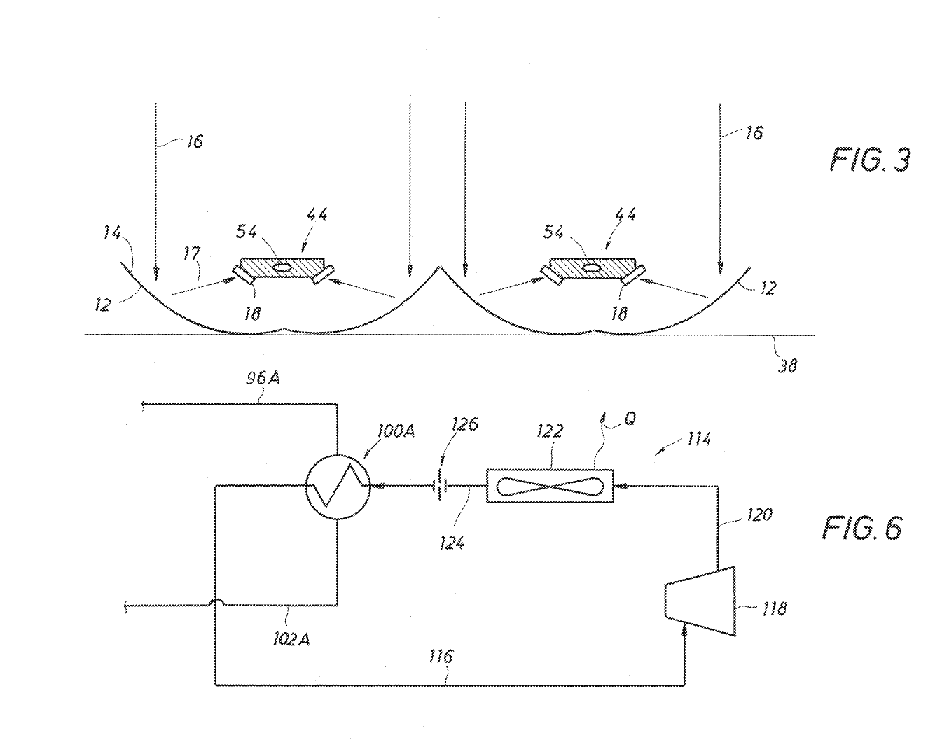

FIG. 3 is a side sectional view of a portion of the array 40 of FIG. 2 and taken along lines 3-3. In this example, solar rays 16 are shown being directed towards the reflective surface of the collectors from which the reflected rays 17 are directed towards receivers 18 mounted on beams 44. In the example of FIG. 3, the beams 44 are substantially parallel with the lower surface of the housing 38 so that the receivers 18 are set at an angle oblique to the generally rectangular cross section of the beams 44. A flow channel 54 is illustrated formed longitudinally through the beam 44 that is in fluid communication with lines 30₁, 30₂ and 34₁, 34₂ via the fittings 50. In the example of FIG. 3, heat Q makes its way from the receiver 18 into the beam 44 where it is transferred to fluid within the flow channel 54 for transport to the heat exchanger 32 (FIG. 1). Thus, by the forced convection of a heat transfer fluid through the array 40, temperature within the receivers 18 may be maintained at a desired level.

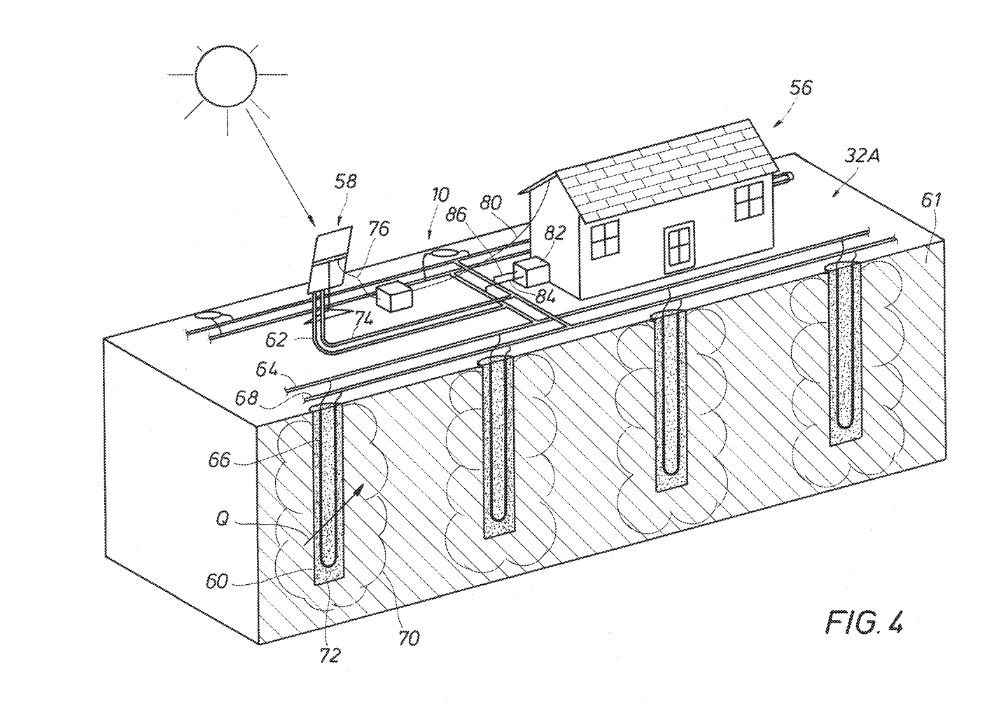

Shown in a side perspective view in FIG. 4 is one example embodiment of the solar energy collection system 10 used in conjunction with a structure 56. In the example of FIG. 4, the structure 56 may be a residence, business, or any other facility that may consume electricity and require some form of conditioned air therein. Shown external to the structure 56 and in a path of solar rays 16 is a solar unit 58 that in one example is made up of a collection of solar arrays 40 (FIG. 2). Also illustrated are a series of wellbores 60 that are vertically formed into subterranean formation 61 beneath the structure 56. A heated flow line 62 connects to the solar unit 58 for carrying fluid away from the unit 58 that has been heated via thermal contact with one or more receivers 18 (FIG. 1) in the unit 58. The heated flow line 62 connects to a supply header 64 that is designed to distribute heated fluid from the solar unit 58 to the wellbores 60. Flow loops 66 are illustrated suspended within each of the wellbores 60 that have an inlet in fluid communication with the supply header 64 and an exit in fluid communication with a return header 68. As the fluid flows from the supply header 64 and through the flow loops 66 to the return header 68, heat Q within the fluid is transferred into the formation and forms heated zones 70, represented by the clouded lines outside of each of the wellbores 60. An optional packing 72 may be provided in the wellbores 60 with the flow loops 66 to enhance heat transfer from the flow loops 66 and to the formation 61. Examples of packing 72 include crushed limestone, metallic particles, semi-metallic particles, other mineral type substances, or combinations. In an example embodiment, the packing 72 enables heat transfer and also support for the flow loops 66. A return line 74 returns the cooled heat transfer fluid from the return header 68 into the array unit 58 for absorption of additional heat from the unit 58. In one example embodiment, the wellbores 60 can have depths of up to around 500 foot and the heated zone 70 can be heated to temperatures of from about 10° F. to about 20° F. above their normal temperatures. Thus, depending on the normal subterranean temperature of the formation 61, the heated zone 70 may reach temperatures of from about 60° F. to about 70° F. after being heated with the heated fluid.

An electrical output line 76 for transmitting electricity generated in the unit 58 is illustrated in the embodiment of FIG. 4, where the output line 76 has one end connected to the array unit 58 and another end to an optional control unit 78. The control unit 78 can process electricity generated within the array unit 58 for usage within the structure 56. Thus the control unit 78 may include an inverter, rectifier, wave shaping features, or other devices for conditioning electrical power. Regulation of electrical current flow may also be accomplished within the control unit 78. A supply line 80 is illustrated connected between the control unit 78 and structure 56 for delivering electrical power to the structure 56 for usage therein.

In one non-limiting example of use, during the warmer months or seasons, heat Q is continuously transferred from the array unit 58 into the heated zones 70 through the heat transfer system. As subterranean strata can retain almost all of its stored heat, and is largely unaffected by temperature ambient to the structure 56, the heat Q can be accumulated during the warmer months and then harvested when ambient temperature dictates heating needs within the structure 56. For example, heat Q may be harvested from the array unit 58 in roughly the timeframe from May into September and then stored within the formation 61 within the heated zones 70 until such time that heating is required within the structure 56, such as for example from about November through April. Depending on the number of wellbores 60 and the amount of heat Q stored, the environment in the structure 56 can be conditioned with the heat Q stored within the heated zones 70 during times of cooler ambient temperature.

Further in the example embodiment of FIG. 4, a heat exchanger 82 is shown provided adjacent the structure 56 and connected to each of the supply and return headers 64, 68. As such, during the period of time when heat is being collected and stored in the heated zones 70, the heat exchanger 82 can be isolated, such as by valves (not shown) within the leads 84, 86 that connect the heat exchanger 82 to headers 64, 68. During cooler months and when heating is required, valves (not shown) provided in lines 62, 74 may be closed to isolate the array unit 58 from the flow loops 66 and valves in the leads 84, 86 opened, thereby allowing fluid flow from the heated zones 70 into heat exchanger 82. From the heat exchanger 82, heat from the heated zones 70 can be transferred into the structure 56 for heating within the structure 56. In one example embodiment, efficiency of a solar system described herein is increased from about 32% to about 80% efficiency by removing waste heat from the solar cells 20 (FIG. 1) so they are at a temperature allowing efficient operation and heating the structure 56 with the waste heat. Thus, the function of the heat exchanger 32 of FIG. 1 is assumed by the flow loops 66 and wellbores 60 that operate as a heat exchanger 32A. Although a total of 8 wellbores 60 are illustrated in FIG. 4, any number of wellbores 60 with associated flow loops 66 may be used with the system described herein. In an example embodiment, it is estimated that two wellbores 60 of around 500 feet each could be used for a home having a living space of around 2000 ft². The amount of heat Q stored in the heated zones 70 of the two wellbores 60 can provide sufficient lower quality heat for heating the home for an entire cold weather season. Further, in an example embodiment the two wellbores 60 as a part of an example of the solar energy collection system 10 can supply upwards of about 75% of typical energy usage of the 2000 ft² home.

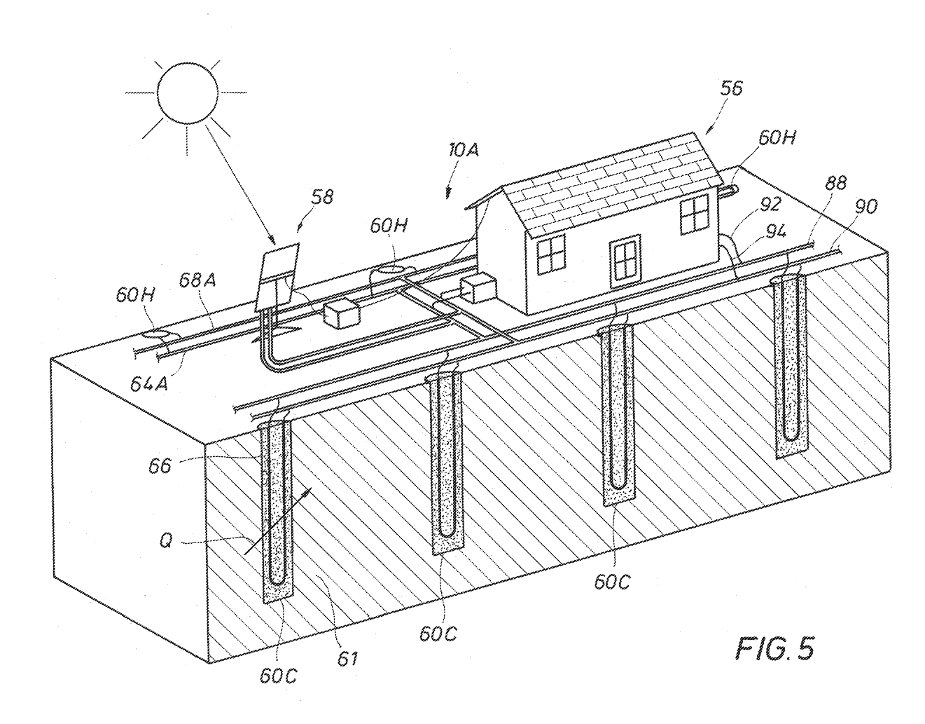

FIG. 5 presents an optional embodiment of a solar energy collection system 10A that uses the wellbores 60 for heating and also for cooling the structure 56. In the example of FIG. 5, heat Q is transferred from the structure 56 to wellbores 60C when needed, and heat Q drawn from wellbores 60H when needed. Wellbores 60C contain flow loops 66 connected to cooling headers 88, 90 that transfer heat from the wellbores 60C to the structure 56 via lines 92, 94. However, headers 88, 90 are part of a heat transfer circuit that is not connected to the array unit 58 and thus not subject to the heating provided by the receivers 18 (FIG. 1) therein. In contrast, in warmer months, and times when ambient temperatures might dictate the use of cooling air within the structure 56, heat Q from within the structure 56 may be transferred through line 92, header 88, and into the subterranean formation 61 with heat transfer fluid. In the example of FIG. 5 however, wellbores 60H are part of the heat transfer circuit connected to the array unit 58 so that geothermal wells can provide cooling to the structure 56 in warmer months and yet still provide heating to the structure 56 in cooler months. Yet further optionally, the heat Q transferred into the formation 61 through wellbores 60C from the structure 56 may then later be transferred back into the structure 56 during times of cooler temperatures.

Referring back to FIG. 1, the heat transfer circuit representing the transfer of heat from the wellbores 60 (FIG. 4) to the structure 56 is depicted as a consuming branch 96. As such, the heat exchanger 32 and associated piping is referred to herein as a charging branch. The charging branch 96 is shown made up of a line 98 connecting to flow line 30 and terminating in the inlet of a heat exchanger 100. Heat Q is being extracted from the heat exchanger 100 that may be used for heating the structure 56. Line 102 connects to an exit of the heat exchanger 100 and terminates in line 34 downstream of heat exchanger 32. Valve 104 is shown provided in flow line 30 upstream of the branch to line 98 and the valve 106 is shown set in line 98 upstream of the heat exchanger 100. Similarly, a valve 108 is set in line 102 downstream of heat exchanger 100. Finally, valve 110 is set in line 34 in the portion downstream of the branch with line 102 and upstream of pump 36. In an example embodiment, each of the valves 104, 106, 108, 110 may be motor operated and thereby selectively and remotely opened, closed (either fully or partially). Each of the valves 104, 106, 108, 110 are shown connected via telemetry to a controller 112 that may accomplish the function of sending opening and closing control signals. Yet further optionally, the controller 112 may be connected by telemetry to pump 36. In an example, selective control of heat transfer fluid flow through the system may be accomplished through selective opening and shutting of valves 104, 106, 108, 110, thereby selectively directing flow through either the heat exchanger 32 and/or heat exchanger 100. Moreover, the controller 112 can be programmed to direct flow accordingly so that the structure 56 is maintained at a preset temperature. Temperature sensors (not shown) may be relied on for use with the controller 112, where the sensors can be disposed in one or more of the lines in the heat exchanger circuit(s) as well as in the structure 56. Temperature overrides, such as from a thermostat (not shown) in the structure 56 may control operation of the controller 112.

An example embodiment of how heat Q may be extracted from the fluid flow in line 96 for use in the structure 56 is schematically represented in FIG. 6. In this example, fluid in a heat transfer circuit 114 flows through tubes provided in heat exchanger 100A. The fluid in heat transfer circuit 114 downstream of heat exchanger 100A is a gas that is transported via line 116 from heat exchanger 100A to compressor 118. The gas in line 116 is heated by fluid flowing through lines 96A, 102A and the shell side of heat exchanger 100A. The fluid in lines 96A, 102A may flow from heat exchanger 32 (FIG. 1) i.e. wellbores 60 (FIG. 4). Pressurized gas exits compressor 118 and flows through line 120 to heat exchanger 122. In the example of FIG. 6 heat exchanger 122 is a fan cooler, heat Q is transferred from the pressurized and heated gas to air flowing over tubes carrying the gas. The heated air can be directly used to heat the structure 56.

For the purposes of discussion herein, quality of heat is a relative term that relates to heat energy within a particular medium, wherein higher quality heat describes heat in a medium having a higher heat energy that heat in the medium at a different time or location or in a different medium. In one example, the heat Q transferred from the receiver 18 to the heat transfer circuit 28 (FIG. 1) may be referred to as higher quality heat, whereas heat Q stored in the wellbores 60 (FIG. 4) may be referred to as lower quality heat. Described herein is how higher quality heat may be converted to lower quality heat and the converted lower quality heat stored for a period of time. For example, the higher quality heat Q from receiver 18 (FIG. 1) is transferred to heat exchanger 32 (or wellbore 60 in FIG. 4) where the heat Q is stored in the formation as lower quality heat. Further illustrated herein is how the stored lower quality heat may be converted back into a form of higher quality heat and utilized. More specifically, in one example embodiment the heat transfer circuit 114 enables conversion of the lower quality heat Q stored in the formation 61 to higher quality heat for use in heating the structure. Advantages of the example methods described herein include harvesting higher quality heat and converting the heat into a lower quality heat for storage, as higher quality heat tends to dissipate faster than lower quality heat. As such, a greater amount of heat may then be available from storage than if the heat were stored in its higher quality form.

The present invention described herein, therefore, is well adapted to carry out the objects and attain the ends and advantages mentioned, as well as others inherent therein. While a presently preferred embodiment of the invention has been given for purposes of disclosure, numerous changes exist in the details of procedures for accomplishing the desired results. These and other similar modifications will readily suggest themselves to those skilled in the art, and are intended to be encompassed within the spirit of the present invention disclosed herein and the scope of the appended claims.

What is claimed is:

1. A method of processing solar energy comprising:
using a solar cell in the path of solar rays to convert solar energy to electricity and heat;
directing the electricity to a load; and
transferring the heat from the solar cell to a geothermal well.

2. The method of claim 1, further comprising transferring the heat from the geothermal well to a structure for heating the structure.

3. The method of claim 2, wherein ambient temperature when the heat is transferred to the geothermal well exceeds ambient temperature when the heat is transferred from the geothermal well to the structure.

4. The method of claim 2, wherein the geothermal well is a heating geothermal well, the method further comprising transferring heat from the structure to a cooling geothermal well to cool the structure.

5. The method of claim 2, wherein the electricity is used to power the structure and wherein when the heat from the geothermal well is transferred to the structure, the amount of energy within the solar rays transferred to the structure increases from about 30% to about 80%.

6. The method of claim 1, further comprising using a solar collector to reflect and concentrate the solar rays onto the solar cell.

7. The method of claim 1, wherein a flow of fluid thermally communicates with the solar cell and flows into the geothermal well thereby transferring the heat from the solar cell to the geothermal well.

8. A solar energy system comprising:
a solar receiver having a solar cell that is selectively disposed in a path of solar rays and that is in selective electrical communication with an electrical load; and
a heat transfer circuit comprising a charging branch that has a portion in thermal communication with the solar cell and a portion in thermal communication with a geothermal well that defines a selective heat transfer path between the solar cell and the geothermal well, and a consuming branch that has a portion in thermal communication with the geothermal well and a portion in thermal communication with a structure to define a heat transfer path between the geothermal well and the structure.

9. The solar energy system of claim 8, wherein the solar cell comprises a concentrated photovoltaic cell that receives concentrated solar rays.

10. The solar energy system of claim 8, wherein the heat transfer circuit comprises fluid flow lines that transport a heat transfer fluid and wherein valves in the heat transfer circuit selectively open and close to divert the heat transfer fluid along a designated heat transfer path.

11. The solar energy system of claim 8, wherein the electrical load is disposed in the structure.

12. The solar energy system of claim 8, wherein energy in the solar rays is converted to heat and electricity in the solar receiver is transferred to the structure at an efficiency of about 80%.

13. The solar energy system of claim 8, wherein the heat transfer circuit comprises a heat transfer fluid that selectively flows through a conduit formed in the solar receiver.

14. A solar energy system comprising:
a curved solar collector having a reflective convex surface shaped to reflect and concentrate solar rays into an image;
a solar receiver having a solar cell strategically disposed to receive the image thereon;
electrically conducting leads that connect the solar cell to an electrical load disposed in a structure;
a heat transfer circuit comprising;
an energizing branch that is in thermal communication with the solar cell and a geothermal well so that a heat transfer path is defined between the solar cell and geothermal well, and
a dissipating branch that is in thermal communication with the geothermal well and the structure, so that a heat transfer path is defined between the geothermal well and the structure.

15. The solar energy system of claim 14, wherein the energizing branch and dissipating branch comprise conduit for transporting fluid having a heat capacity.

16. The solar energy system of claim 15, further comprising valves in the heat transfer circuit that selectively open and close so that the fluid is flowing through the energizing branch or the dissipating branch.

17. The solar energy system of claim 15, wherein the geothermal well is a substantially vertical borehole and a portion of the heat transfer circuit comprises conduit that is suspended in the borehole and a heat transfer medium is provided between the conduit and walls of the borehole.
